(19) United States
(12) Patent Application Publication
(10) Pub. No.: US 2026/0112555 A1
(43) Pub. Date: Apr. 23, 2026

(54) INDUSTRIAL CUT-OFF SWITCH FOR PROVIDING VISUAL INFORMATION ON HIGH CURRENT CONDUCTION STATE OF ENCLOSURE

(71) Applicant: HYUNDAI TECH CO., LTD., Seoul (KR)

(72) Inventor: Jae Gyo JUNG, Seoul (KR)

(73) Assignee: HYUNDAI TECH CO., LTD., Seoul (KR)

(21) Appl. No.: 19/429,080

(22) Filed: Dec. 22, 2025

Related U.S. Application Data
(63) Continuation of application No. PCT/KR2024/008557, filed on Jun. 20, 2024.

(30) Foreign Application Priority Data
Jun. 20, 2023 (KR) 10-2023-0078726

(51) Int. Cl. H01H 19/10; H01H 9/02

(52) U.S. Cl. CPC H01H 19/10; H01H 9/02

(57) ABSTRACT

Provided is an industrial cut-off switch including: the enclosure comprising a main body of which one surface is open and which has an accommodation space therein, and a door which is disposed on the open one surface of the main body so as to be opened and closed and is hinge-coupled to one side of the main body; a handle disposed on the outer surface of the enclosure and having a gripping portion extending in one direction; a switch unit which is disposed inside the enclosure and is connected to the handle such that an on/off operation thereof is controlled by means of the manipulation of the handle; and an electric leakage notification unit for sensing the high current conduction of the enclosure and providing visual information enabling the high current conduction state of the enclosure to be checked from the outside through a window formed on the door.

### CROSS-REFERENCE TO RELATED APPLICATIONS

This application is a continuation of International Application No. PCT/KR2024/008557 filed on Jun. 20, 2024, which claims priority to Korean Patent Application No. 10-2023-0078726 filed on Jun. 20, 2023, the entire contents of which are herein incorporated by reference.

### TECHNICAL FIELD

The present disclosure relates to an industrial cut-off switch.

### BACKGROUND ART

In general, a circuit breaker is a device that interrupts a current being conducted, and an operator uses the circuit breaker to cut off current supplied to a machine in order to safely inspect or repair the machine to which the current is being supplied.

A conventional circuit breaker was turned on and off with a button-type switch to cut off the supply of external power. Not only because of its small size, but also because of its structural characteristics, the pressed state of the button-type switch was not clearly visible. There was a problem where the operator inspecting the machine from a distance from the circuit breaker had difficulty recognizing the on/off state of the circuit breaker.

In addition, the operator may come into contact with a busbar or wiring while manipulating the button-type switch exposed to the outside, and if a leakage current occurs in the circuit breaker, a large current may flow through an enclosure, thereby easily exposing the operator to the risk of electric shock.

Accordingly, in order to solve the above-described problems, the inventor of the present disclosure conducted extensive research and repeated trials and errors, ultimately completing the present disclosure.

### DISCLOSURE OF THE INVENTION

### Technical Goals

The present disclosure has been made in order to solve the problems described above, and an object of the present disclosure is to provide an industrial cut-off switch that enables whether power is cut off and whether there is a current leak in the enclosure to be easily recognized with the naked eye, from the outside.

In addition, an object of the present disclosure is to provide a method for safe operation without the risk of electric shock during the process of cutting off power.

Technical objects to be achieved by the present disclosure are not limited to the technical objects described above, and other technical objects not mentioned may be clearly understood by a person skilled in the art to which the present disclosure pertains from the description below.

### Technical Solutions

According to an aspect of the present disclosure for solving the above-described problems, there is provided an industrial cut-off switch including: an enclosure including a main body of which one surface is open and which has an accommodation space therein, and a door which is disposed on the open one surface of the main body so as to be opened and closed and is hinge-coupled to one side of the main body; a handle disposed on an outer surface of the enclosure and having a gripping portion extending in one direction; a switch unit which is disposed inside the enclosure and is connected to the handle such that an on/off operation thereof is controlled by means of manipulation of the handle; and an electric leakage notification unit configured to sense high current conduction of the enclosure and provide visual information enabling a high current conduction state of the enclosure to be checked from the outside through a window formed on the door, wherein the handle is connected to the enclosure so as to be rotatable around a point at which it is attached to the outer surface of the enclosure and turns the switch unit on and off at predetermined rotational positions so that a user can recognize the on/off of the switch unit.

According to a preferred embodiment of the present disclosure, the industrial cut-off switch may include an electric shock prevention unit which is connected to an external power source and configured to control conduction of the external power in response to opening and closing of the door.

According to a preferred embodiment of the present disclosure, the industrial cut-off switch may include a protruding member disposed on an inner surface of the door, and a fixing member disposed on an inner surface of the main body such that, when the door is closed, the fixing member is positioned to face the protruding member, wherein the electric shock prevention unit may include a body which is fixed by being fitted into the fixing member, a pair of conduction bars disposed on one side of the body and extending in one direction, and a push bar which is disposed on another side of the body and inserted by external pressure to cause the conduction of the external power, and the electric shock prevention unit may apply pressure to the push bar of the fixing member as the door is being closed to maintain the conduction of the external power when the door is closed, and release the pressure on the push bar as the door is being opened to interrupt the conduction of the external power when the door is opened.

According to a preferred embodiment of the present disclosure, the industrial cut-off switch may include a stopper device which is disposed adjacent to an end of another side of the main body where no hinge coupling with the door is formed, and when operated, keeps the door in an open state, wherein the stopper device may include a stopper unit configured to, when the stopper device is operated, advance toward contact surfaces between the main body and the door on the other side to separate the main body and the door from each other and to keep the door in the open state, and a stopper driving unit configured to propel a plurality of stopper units toward the contacts surface between the main body and the door on the other side by using an internal elastic device when a predetermined trigger is activated.

According to a preferred embodiment of the present disclosure, each of the main body and door may be formed to include a guide portion and a fixing jaw configured to assist the operation of the stopper device at the end of the other side where no hinge coupling is formed, the guide portion may be configured to reduce friction with an entering portion of the advancing stopper unit and guide a tip of the entering portion to advance between the main body and the door, and the fixing jaw may be configured to limit a moving range of the stopper unit to a predetermined range by colliding with a braking portion of the advancing stopper unit and to position a contact prevention portion of the operated stopper unit between the contact surfaces located at the end of the other side.

According to a preferred embodiment of the present disclosure, the industrial cut-off switch may include a stopper operating plate formed on a side portion or a lower portion of the main body with a predetermined minimum area, the stopper operating plate being configured to be drawn into the enclosure by external pressure applied to the formed area so as to activate the trigger and operate the stopper device.

### Advantageous Effects

The present disclosure has an effect of providing an industrial cut-off switch that enables whether an external power source is cut off and whether there is a current leak in the enclosure to be easily checked with the naked eye, even from a distance.

In addition, the present disclosure has an effect of providing an industrial cut-off switch that enables safe operation without electric shock accidents during the process of cutting off power.

It should also be noted that any effects described in the following and any potential effects expected from the technical features of the present disclosure shall be regarded as being included in the present specification, even if the effects are not explicitly mentioned herein.

### BRIEF DESCRIPTION OF DRAWINGS

FIG. 1 is a front view of a cut-off switch according to the present disclosure.

FIG. 2 is a side view of a cut-off switch according to the present disclosure.

FIG. 3 is a front view of the interior of a cut-off switch according to the present disclosure.

FIG. 4 is a side view of the interior of a cut-off switch according to the present disclosure.

FIGS. 5A and 5B illustrate a modified example of portion A of FIG. 2.

FIGS. 6 to 8 are reference diagrams for explaining a leakage prevention configuration according to the present disclosure.

FIG. 9 and FIG. 10 are reference diagrams for explaining a handle according to an embodiment of the present disclosure.

FIG. 11 is a reference diagram for explaining a leakage prevention configuration through a handle according to an embodiment of the present disclosure.

### DETAILED DESCRIPTION OF THE INVENTION

In describing the present disclosure, detailed explanations of well-known functions that are apparent to those skilled in the art will be omitted when it is determined that such descriptions would unnecessarily obscure the gist of the disclosure.

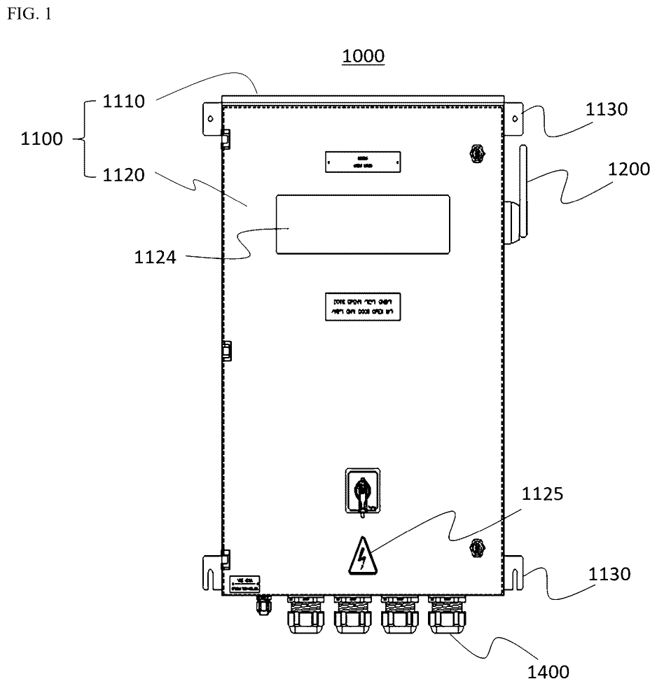

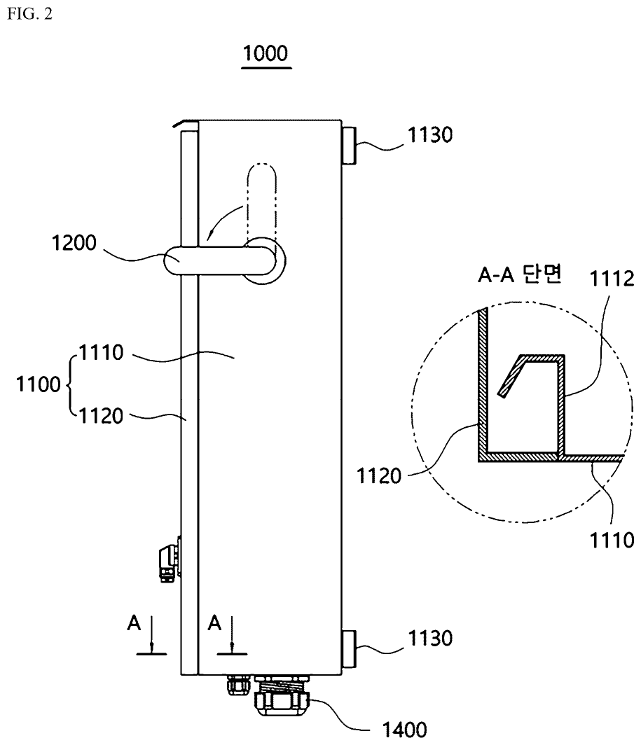

FIG. 1 is a front view of a cut-off switch 1000 according to the present disclosure. FIG. 2 is a side view of the cut-off switch 1000 according to the present disclosure. As can be seen in FIGS. 1 and 2, the cut-off switch 1000 according to the present disclosure includes an enclosure 1100, a handle 3000, and a switch unit 1300.

The enclosure 1100 includes an accommodation space capable of accommodating mechanisms, devices, or the like therein. The shape of the enclosure 1100 may be varied, and in the cut-off switch 1000, the enclosure 1100 has a rectangular parallelepiped shape and is provided, in its internal accommodation space, with a switch unit 1300, a busbar 1510, and the like, which will be described later.

The handle 3000 controls the switch unit 1300 to be described later and is disposed on an outer surface of the enclosure 1100. The handle 3000 has a shape extending in one direction so that it can be easily gripped by a user's hand. The handle 3000 is connected to the enclosure 1100 so as to be rotatable around a point at which it is attached to the outer surface of the enclosure 1100. The handle 3000 turns the switch unit 1300 on and off at predetermined rotational positions so that the user can easily recognize whether the switch unit 1300 is in the on or off state. In addition, the user may check the interior of the enclosure 1100 through a window 1124 of a door 1120 which will be described later at a close distance to check whether the switch unit 1300 is in the on or off state.

The switch unit 1300 is disposed inside the enclosure 1100 and is connected to the handle 3000 to perform on/off control of external power supply by means of manipulation of the handle 3000 disposed on the outer surface of the enclosure 1100.

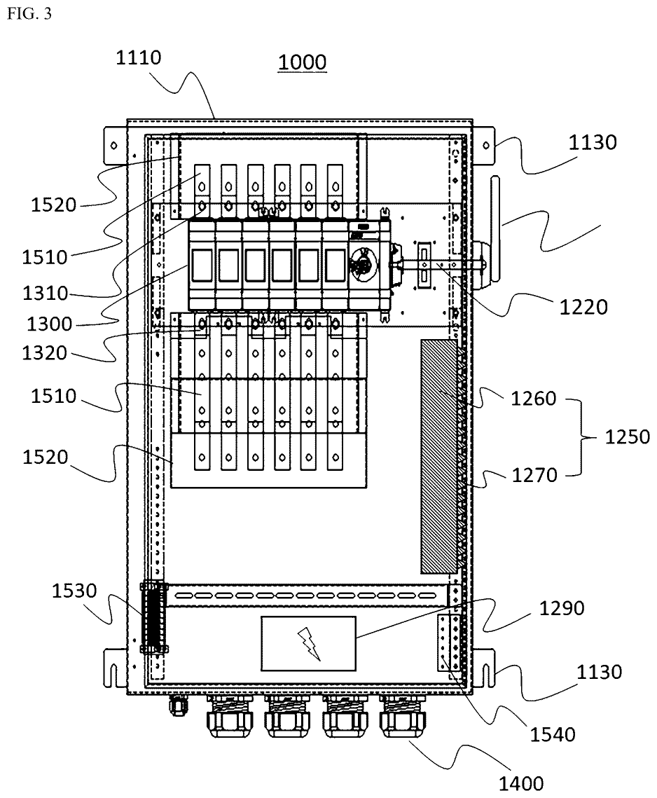

FIG. 3 is a front view of the interior of the cut-off switch 1000 according to the present disclosure. As can be seen in FIG. 3, the switch unit 1300 includes a first connecting portion 1310 and a second connecting portion 1320 that are electrically connected to the busbar 1510 to be described later.

The first connecting portion 1310 extends upward from an upper surface of the switch unit 1300, and the second connecting portion 1320 extends downward from a lower surface of the switch unit 1300. The first connecting portion 1310 is connected so as to be in electrical conduction with an external power source, and the second connecting portion 1320 is connected so as to be in electrical conduction with a power supply device. In other words, the switch unit 1300 is positioned between a line in electrical conduction with the external power source and a line in electrical conduction with the power supply device. The switch unit 1300 turns conduction between the external power source and the power supply device on and off by means of manipulation of the handle 3000. For the above described cut-off switch 1000, the connection targets of the first connecting portion 1310 and the second connecting portion 1320 are specified, but the connection targets are not necessarily limited thereto. The first connecting portion 1310 may connected so as to be in electrical conduction with the power supply device, and the second connecting portion 1320 is connected so as to be in electrical conduction with the external power source.

The handle 3000 includes a shaft unit 1220 which penetrates the enclosure 1100, is coupled to the switch unit 1300, and extends in one direction. The shaft unit 1220 transfers rotational energy of the handle 3000 to the switch unit 1300 so that the on/off of the switch unit 1300 is controlled.

The enclosure 1100 of the cut-off switch 1000 according to the present disclosure may completely block inflow of external substances by means of a unique sealing structure. The enclosure 1100 includes a main body 1110 having one surface open and an accommodation space therein. The main body 1110 may be fixed to a wall surface by means of a bracket 1130 coupled to one surface. The enclosure 1100 includes the door 1120 that is disposed to open and close the open surface of the main body 1110 and is hinge-coupled to one side of the main body 1110. The enclosure 1100 may seal the accommodation space by means of the door 1120.

Compared to one side of the main body 1110 on which the door 1120 is disposed, the main body 1110 includes a step 1112 on another side. As can be seen in FIG. 2, the step 1112 extends inward from one surface that contacts the door 1120 in its closed state. The step 1112 is bent at least once so as to face the door 1120. The step 1112 of the cut-off switch 1000 is bent toward the door 1120 side, and further bent in an inclined manner at its end portion, thereby secondarily preventing inflow of external substances.

Further, the cut-off switch 1000 includes busbars 1510 connected to the connecting portions 1310 and 1320 of the switch unit 1300. In addition, as can be seen in FIG. 3, the cut-off switch 1000 includes insulating member plates 1520 disposed in front of the connecting portions 1310 and 1320 to prevent electric shock accidents from the busbars 1510 and the connecting portions 1310, 1320. The insulating member plates 1520 prevents user contact with the connecting portions 1310 and 1320 and the busbars 1510, thereby preventing electric shock accidents. The insulating member plate 1520 is made of a material which hinders electrical conduction, and may be, for example, an acrylic plate. Further, the cut-off switch 1000 includes a terminal block 1530 which can be connected to other wires to form a circuit and an earth bar 1540 which serves as a ground.

In addition, the cut-off switch 1000 according to the present disclosure employs a Y-D (wye-delta) starting method configured with six poles, and thus may perform the role that has conventionally been carried out by two cut-off switches utilizing a Y-D (wye-delta) starting method configured with three poles. Accordingly, even in places with limited installation space, the same operational effect as before may be achieved by installing only one cut-off switch.

For example, in the related art, two cut-off switches of either the 200-A type or the 400-A type had to be operated depending on the load, which increased costs and imposed spatial constraints. However, when the cut-off switch 1000 according to the present disclosure is installed, the cost may be reduced to 80% of that of the conventional configuration, and securing installation space may be facilitated.

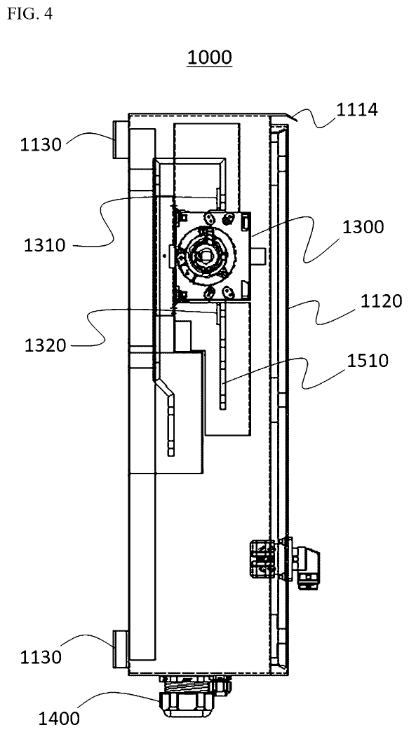

The enclosure 1100 includes a roof portion 1114 to prevent inflow of materials falling from above. As can be seen in FIGS. 2 and 4, the roof portion 1114 extends horizontally from an upper side of the enclosure 1100 and is bent at least once to extend downward in an inclined manner.

FIG. 4 is a side view of the interior of a cut-off switch according to the present disclosure. As can be seen in FIG. 4, the busbar 1510 connected to the first connecting portion 1310 extends downward in a “C”-shaped configuration. The busbar 1510 connected to the second connecting portion 1320 extends downward. Since the ends of the busbars 1510 connected to cables are concentrated and located at a lower portion of the enclosure 1100, management of connecting the cables entering the enclosure 1100 from the outside to the busbars 1510 is facilitated.

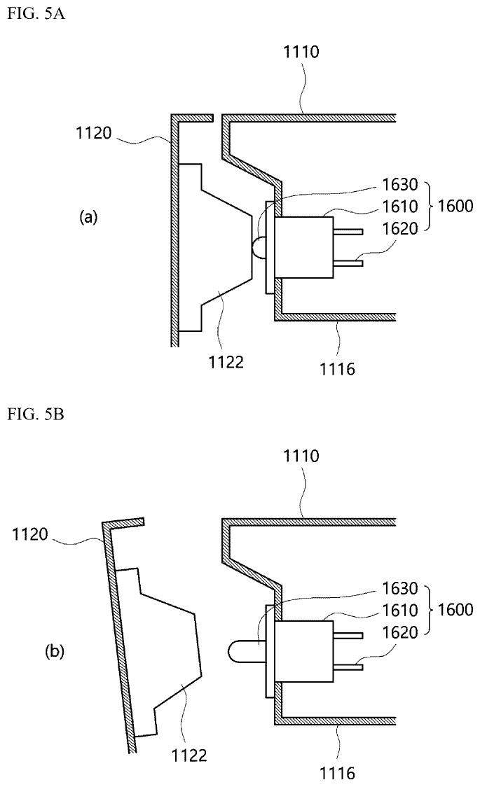

FIGS. 5A and 5B illustrate a modified example of portion A of FIG. 2. In FIG. 5A illustrates a state in which the door 1120 is closed, and FIG. 5B illustrates a state in which the door 1120 is open. As can be seen in FIGS. 5A and 5B, the present disclosure may include an electric shock prevention unit 1600 which is connected to an external power source and controls conduction of external power by opening and closing the door 1120. The external power source is connected to the electric shock prevention unit 1600 before being connected to the switch unit 1300. The electric shock prevention unit 1600 cuts off the external power when the door 1120 is opened, so no power is supplied to the switch unit 1300 while the door 1120 is in the open state.

Specifically, the electric shock prevention unit 1600 includes a body 1610, a conduction bar 1620, and a push bar 1630. The body 1610 is fixed by being fitted into a fixing member 1116 disposed on an inner surface of the main body 1110. The fixing member 1116 is disposed to face a protruding member 1122 disposed on an inner surface of the door 1120 when the door 1120 is in the closed state. The conduction bar 1620 is disposed on one side of the body 1610 and extends in one direction. A pair of the conduction bars 1620 are provided, and each conduction bar is connected so as to be in electrical conduction with the external power source. The push bar 1630 is disposed on another side of the body 1610 and inserted into the body 1610 by external pressure to cause conduction of the external power. In other words, the electric shock prevention unit 1600 applies pressure to the push bar 1630 of the fixing member 1116 as the door 1120 is being closed to cause conduction of the external power, as shown in FIG. 5A, and releases the pressure on the push bar 1630 as the door 1120 is being opened to cut off the external power, as shown in FIG. 5B. Accordingly, the user may safely inspect the interior of the enclosure 1100 by opening the door 1120.

### Example of Leakage Notification and Leakage Prevention

According to an embodiment of the present disclosure, a leakage in the cut-off switch 1000 may be sensed and information regarding the leakage may be transmitted to a user, thereby preventing an electric shock accident caused by the leakage.

First, referring to FIGS. 1 and 3, the cut-off switch 1000 may allow an external user to check a leakage notification through a window 1125 formed in the door 1120 of the enclosure 1100.

Here, the leakage notification is provided by an electric leakage notification unit 1290, which may sense high current conduction of the enclosure and generate and provide visual information enabling a high current conduction state of the enclosure 1100 to be checked from the outside through the window 1125 formed in the door 1120.

Specifically, the electric leakage notification unit 1290 may be equipped with a lamp to notify of a leakage, and when a leakage is sensed, the lamp may be turned on to allow the external user to check the leakage.

In addition, if the cut-off switch 1000 is configured such that the external power is connected to or cut off from the cut-off switch 1000 through the electric shock prevention unit 1600 described above, the external power is cut off from the moment the door 1120 is opened, thereby preventing the risk of electric shock during work. However, it may be difficult to deal with a situation of electric leakage due to a large current which is conducted while the door 1120 is in the closed state.

For example, a leakage may occur when the insulation of components of the electric shock prevention unit 1600 is compromised, and in such a case, a large current may flow through the main body 1110 and the door 1120, thereby posing a risk of electric shock to the user who comes into contact with the cut-off switch 1000 for operation or maintenance.

The cut-off switch 1000 according to the present disclosure may include a stopper device 1250 to prevent electric shock accidents caused by the leakage as described above.

Referring to FIG. 3, the stopper device 1250 may be disposed adjacent to an end of another side of the main body 1110 where no hinge coupling with the door 1120 is formed, and when operated, may keep the door 1120 in the open state.

Specifically, if the cut-off switch 1000 is configured such that the external power is connected to or cut off from the cut-off switch 1000 through the electric shock prevention unit 1600, the external power may be cut off from the moment the door 1120 is opened, thereby preventing the risk of electric shock during work. However, if the door 1120 is closed again during work, the user may be exposed to the risk of electric shock once more.

Further, if a leakage has already occurred when the user initially approaches and attempts to touch the cut-off switch 1000, an electric shock accident may occur before the door 1120 is opened and the external power is cut off, so the leakage condition must be identified in advance and addressed accordingly.

To this end, the electric leakage notification unit 1290 enables the user to check in advance whether a leakage has occurred in the cut-off switch 1000, and the stopper device 1250 allows the door 1120 of the cut-off switch 1000 in which a leakage has occurred to be safely opened without direct user contact and to remain in the opened state, thereby allowing the electric shock prevention unit 1600 to continuously cut off the external power during work.

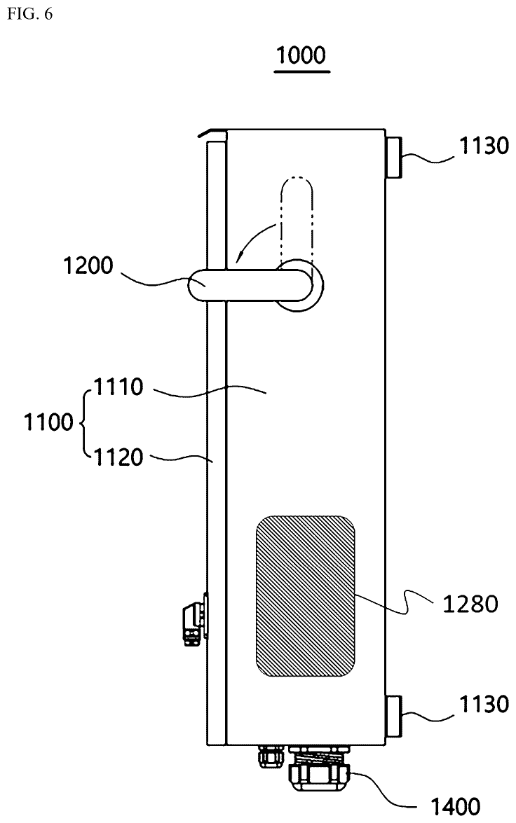

In this regard, FIGS. 6 to 8 are reference diagrams for specifically explaining a leakage prevention configuration of the stopper device 1250 according to an embodiment of the present disclosure.

Referring to FIG. 6, the cut-off switch 1000 according to the present disclosure may include a stopper operating plate 1280.

The stopper operating plate 1280 is formed on a side portion or a lower portion of the main body 1110 with a predetermined minimum area, and may be drawn into the enclosure 1100 by external pressure applied to the formed area so as to activate a trigger and operate the stopper device 1250.

Additionally, the stopper operating plate 1280 may be made of an insulating material such as rubber to minimize the risk of electric shock to the user, and may be formed flat so that the user can easily apply pressure using a kicking motion or a bar-shaped tool.

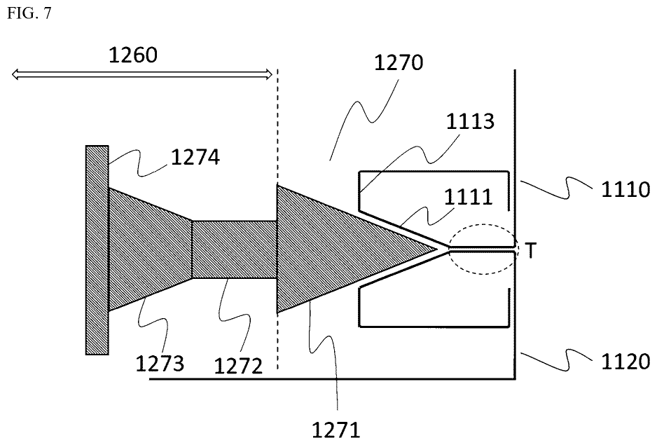

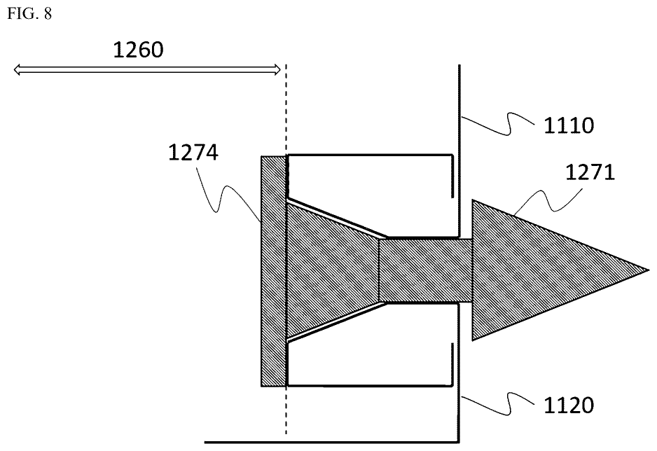

FIG. 7 and FIG. 8 are cross-sectional views viewed from above of the other side where no hinge coupling is formed between the main body 1110 and the door 1120. Referring to FIG. 7 and FIG. 8, the stopper device 1250 may include a stopper unit 1270 which advances toward contact surfaces T between the main body 1110 and the door 1120 on the other side when the stopper device 1250 is operated to separate the main body 1110 and the door 1120 from each other and to keep the door 1120 in the open state. Referring to FIG. 3, a plurality of the stopper units 1270 may be provided to stably maintain the open state of the door 1120, and may be arranged vertically along the contact surfaces T between the main body 1110 and the door 1120 on the other side.

Further, the stopper device 1250 may include a stopper driving unit 1260 which, when a trigger set by pressure applied to the stopper operating plate 1280 is activated, uses an internal elastic device to propel the plurality of stopper units 1270 to advance toward the contact surfaces T between the main body 1110 and the door 1120 on the other side.

In addition, each of the main body 1110 and the door 1120 may be formed to include a guide portion 1111 and a fixing jaw 1113 configured to assist the operation of the stopper device 1250 at the end of the other side where no hinge coupling is formed.

Specifically, the stopper unit 1270 may be configured to include an entering portion 1271, a contact prevention portion 1272, a support portion 1273, and a braking portion 1274.

The entering portion 1271 may be formed in a shape to enter between the contact surfaces T of the main body 1110 and the door 1120 as the stopper unit 1270 advances, thereby separating the two contact surfaces T from each other. For example, the entering portion 1271 may be formed in a conical shape having an inclined surface.

The contact prevention portion 1272 is positioned to prevent the two contact surfaces T from making contact when the entry of the stopper unit 1270 through the entering portion 1271 is completed, thereby keeping the door 1120 in the open state.

The support portion 1273 serves to support a structure formed at the end of the other side where no hinge coupling is formed between the main body 1110 and the door 1120 so that the structure does not become deformed.

Specifically, the support portion 1273 may be formed to have an inclined surface with an inclination angle corresponding to that of the entering portion 1271. Accordingly, when the door 1120 rotates in a closing direction and collides with the stopper unit 1270, the guide portion 1111 may be stably supported, and a situation in which the shape of an end-side structure is deformed, such as the angle of inclination of the guide portion 1111 being distorted, may be prevented.

The braking portion 1274 plays a role in preventing the stopper unit 1270 from advancing any further by colliding with the end-side structure such as the fixing jaw 1113 described later. A rear surface of the braking portion 1274 may be directly or indirectly connected to the elastic device of the stopper driving unit 1260 to apply pressure so that the stopper unit 1270 is propelled.

The guide portion 1111, which is a structural component of the end, may be formed to have an inclined surface corresponding to the entering portion 1271 of the advancing stopper unit 1270, thereby reducing friction with the entering portion 1271, and may guide a tip of the entering portion 1271 to advance between the main body 1110 and the door 1120.

The fixing jaw 1113, which is a structural component of the end, may collide with the braking portion 1274 of the advancing stopper unit 1270 to limit a moving range of the stopper unit 1270 to a predetermined range, and allow the contact prevention portion 1272 of the operated stopper unit 1270 to be positioned between the contact surfaces T located at the end on the other side.

### Example of Handle Using Multiple Locks

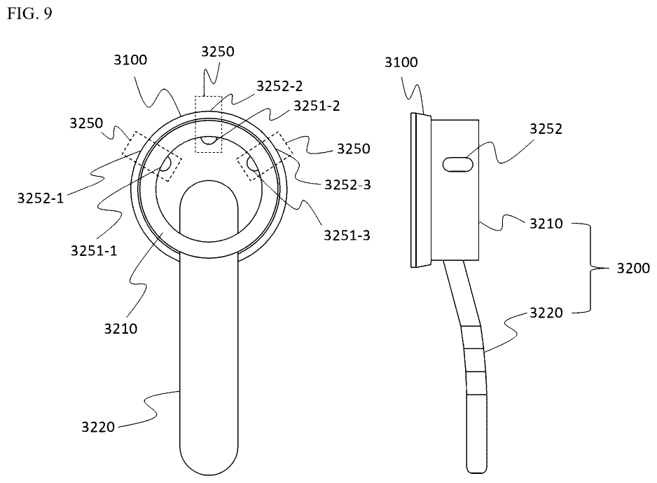

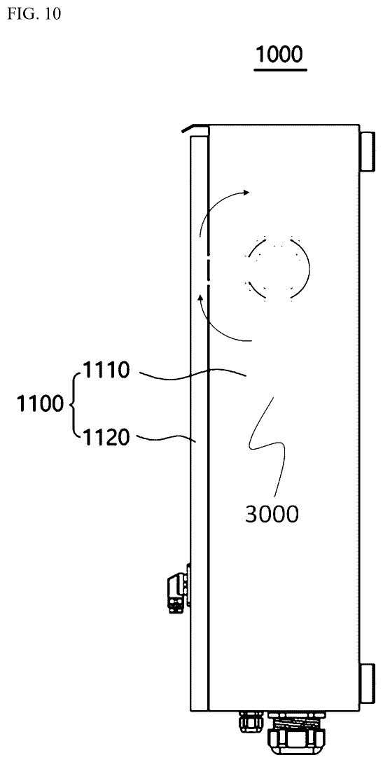

FIG. 9 and FIG. 10 are reference drawings for explaining a handle according to an embodiment of the present disclosure.

Referring to FIGS. 9 and 10, the handle 3000 includes a fixing unit 3100 formed on an outer surface of the enclosure 1100 of the industrial cut-off switch.

Further, the handle 3000 is formed to be rotatable while covering one side of the fixing unit 3100, and includes a rotation unit 3200 which is connected to the shaft unit 1220 extending from the switch unit 1300 inside the enclosure 1100 and rotates the shaft unit 1220 together as it rotates to change the on/off state of the switch unit 1300.

In addition, the handle 3000 is provided with a plurality of locking means 3250, and the rotation unit 3200 is formed such that it can be rotated in one direction to the limit of its rotational operating range to change the switch unit 1300 to the on state when all of the provided locking means 3250 are unlocked.

According to an embodiment of the present disclosure, the rotation unit 3200 is configured to be able to gradually rotate by a predetermined range by an external force whenever each locking means 3250 provided in the handle is unlocked, so that the degree of unlocking of the handle 3000 may be visually checked.

For example, as shown in FIG. 10, when the switch unit 1300 is set to be in the off state while a gripping unit of the handle 3000 is oriented vertically downward with respect to the ground, and the switch unit 1300 is set to be in the on state while the gripping unit of the handle 3000 is oriented vertically upward with respect to the ground, the total rotational movement range of the rotation unit 3200 becomes 180 degrees. Here, when a total of three locking means are provided, the rotation unit may be configured to be gradually rotatable by 60 degrees each time the lock of one locking means 3250 is unlocked.

In addition, the switch unit 1300 may be configured to be switchable to the on state when all of the plurality of locking means 3250 provided in the handle 3000 are unlocked according to a predetermined unlocking sequence set for the plurality of locking means 3250.

For example, when the handle is provided with a total of three locking means, a unique unlocking sequence may be set for each locking means. Specifically, if the locking means designated as the first priority is not unlocked first, the rotation unit 3200 of the handle cannot rotate at all. In such a case, all of the locking means may need to be returned to the locked state, and the unlocking operation must then be performed starting from the locking means designated as the first priority.

In addition, the fixing unit 3100 may include an inner rotation locking ring in which a plurality of first locking holes 3251 are horizontally arranged to correspond to a curvature, and the rotation unit 3200 may include an outer rotation locking ring 3210 which is formed to cover the inner rotation locking ring and in which second locking hole 3252 are horizontally arranged to correspond to the first locking holes 3251.

Here, a pair of the first locking hole 3251 and the second locking hole 3252 corresponding to each other constitute one locking means 3250, and may provide a locking function by using a locking device which is fastened in a state of passing through the pair of the first locking hole 3251 and the second locking hole 3252.

In addition, the inner rotation locking ring rotates together with the rotation unit 3200 as the rotation unit 3200 rotates, and whenever each locking means 3250 is unlocked, detects the unlocking and permits the rotation unit 3200 to rotate in one direction by a predetermined range. As the rotation of the rotation unit 3200 is permitted, the inner rotation locking ring may close the first locking hole 3251 of the most recently unlocked locking means 3250 each time the rotation unit 3200 rotates by the predetermined range in the one direction, and open the first locking holes 3251 in the reverse order of their closure each time the rotation unit 3200 rotates by the predetermined range in the opposite direction.

Accordingly, multiple users who intend to fasten the locking device to the locking means 3250 of the handle may avoid confusion regarding the position of the locking means which each user must lock after the completion of work at the industrial site.

For example, in the process of changing the switch unit 1300 from the on state to the off state, a specific first locking hole (one of 3151-1 to 3151-3) may be opened at each predetermined rotational range. Specifically, as shown in FIG. 4, when three locking means 3250 are provided in total and a first locking hole 3151-1 of the locking means 3250 including the first locking hole 3151-1 and a second locking hole 3152-1 is opened first during the process of switching the switch unit 1300 of the cut-off switch to the off state, the worker who performed the last unlocking operation may identify the locking means 3250 in which the first locking hole 3151-1 is opened and fasten the locking device which passes through the first locking hole 3151-1 and the second locking hole 3152-1. Subsequently, the worker who performed the intermediate unlocking operation may identify the opened first locking hole (3251-2 or 3251-3) and fasten the locking device thereto.

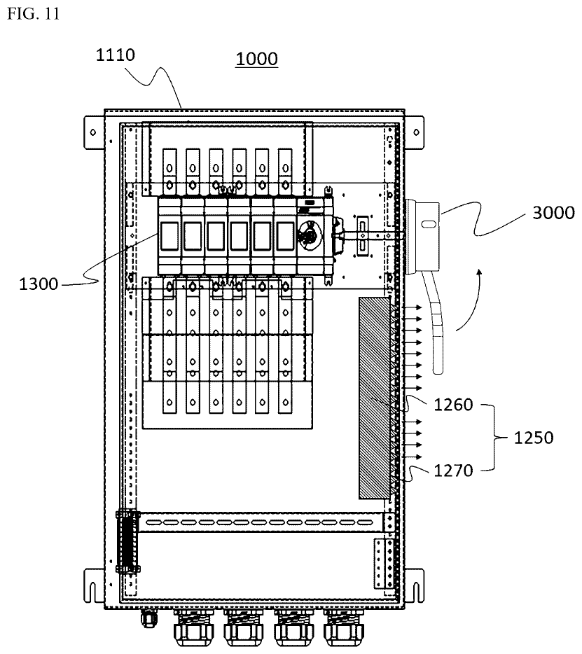

FIG. 11 is a reference diagram for explaining a leakage prevention configuration through a handle according to an embodiment of the present disclosure.

Referring to FIG. 11, when the rotation unit 3200 of the handle 3000 rotates in the opposite direction up to the limit of its rotational operating range due to external pressure applied to a gripping unit 3220, the stopper device 1250 may be actuated to open the door and cut off the external power.

In addition, the handle 3000 may be made of a material such as rubber in order to minimize the risk of electric shock to the user and to provide a certain level of frictional force, thereby allowing the user to easily apply pressure and rotate the handle by performing a kicking motion or by using a bar-shaped tool.

It will be apparent to those skilled in the art that the present disclosure may be embodied in various other specific forms without departing from the characteristics of the present disclosure. Accordingly, the above detailed description should not be construed as limiting in any respect and should be considered as illustrative. The scope of the present disclosure should be determined by a reasonable interpretation of the appended claims, and all changes within the equivalent scope of the present disclosure are included in the scope of the present disclosure.

What is claimed is:

1. An industrial cut-off switch for providing visual information on a high current conduction state of an enclosure, the industrial cut-off switch comprising:
the enclosure comprising a main body of which one surface is open and which has an accommodation space therein, and a door which is disposed on the open one surface of the main body so as to be opened and closed and is hinge-coupled to one side of the main body;
a handle disposed on an outer surface of the enclosure and having a gripping portion extending in one direction;
a switch unit which is disposed inside the enclosure and is connected to the handle such that an on/off operation thereof is controlled by means of manipulation of the handle;
an electric leakage notification unit configured to sense the high current conduction of the enclosure and provide visual information enabling the high current conduction state of the enclosure to be checked from the outside through a window formed on the door; and
a stopper device which is disposed adjacent to an end of another side of the main body where no hinge coupling with the door is formed, and when operated, keeps the door in an open state,
wherein the handle is connected to the enclosure so as to be rotatable around a point at which it is attached to the outer surface of the enclosure and turns the switch unit on and off at predetermined rotational positions so that a user can recognize the on/off of the switch unit,
wherein the stopper device comprises:
a stopper unit configured to, when the stopper device is operated, advance toward contact surfaces between the main body and the door on the other side to separate the main body and the door from each other and to keep the door in the open state; and
a stopper driving unit configured to propel a plurality of stopper units toward the contacts surface between the main body and the door on the other side by using an internal elastic device when a predetermined trigger is activated.

2. The industrial cut-off switch of claim 1, comprising an electric shock prevention unit which is connected to an external power source and configured to control conduction of the external power in response to opening and closing of the door.

3. The industrial cut-off switch of claim 2, comprising:
a protruding member disposed on an inner surface of the door; and
a fixing member disposed on an inner surface of the main body such that, when the door is closed, the fixing member is positioned to face the protruding member,
wherein the electric shock prevention unit comprises:
a body which is fixed by being fitted into the fixing member;
a pair of conduction bars disposed on one side of the body and extending in one direction; and
a push bar which is disposed on another side of the body and inserted by external pressure to cause the conduction of the external power, and
the electric shock prevention unit applies pressure to the push bar of the fixing member as the door is being closed to maintain the conduction of the external power when the door is closed, and releases the pressure on the push bar as the door is being opened to interrupt the conduction of the external power when the door is opened.

4. The industrial cut-off switch of claim 1, wherein each of the main body and door is formed to comprise a guide portion and a fixing jaw configured to assist the operation of the stopper device at the end of the other side where no hinge coupling is formed,
the guide portion is configured to reduce friction with an entering portion of the advancing stopper unit and guide a tip of the entering portion to advance between the main body and the door, and
the fixing jaw is configured to limit a moving range of the stopper unit to a predetermined range by colliding with a braking portion of the advancing stopper unit and to position a contact prevention portion of the operated stopper unit between the contact surfaces located at the end of the other side.

5. The industrial cut-off switch of claim 1, comprising a stopper operating plate formed on a side portion or a lower portion of the main body with a predetermined minimum area, the stopper operating plate being configured to be drawn into the enclosure by external pressure applied to the formed area so as to activate the trigger and operate the stopper device.
